(19) United States
(12) Patent Application Publication
(10) Pub. No.: US 2006/0205114 A1
(43) Pub. Date: Sep. 14, 2006

(54) Packing material for wafer

(75) Inventor: Hirohisa Matsushita, Miyazaki-shi (JP)

Correspondence Address: OLIFF & BERRIDGE, PLC, P.O. BOX 19928, ALEXANDRIA, VA, 22320, US

(73) Assignee: EPSON TOYOCOM CORPORATION, KANAGAWA (JP)

(21) Appl. No.: 11/369,960

(22) Filed: Mar. 8, 2006

(30) Foreign Application Priority Data
Mar. 10, 2005 (JP) 2005-067361
Mar. 3, 2006 (JP) 2006-057525

(51) Int. Cl. H01L 21/00

(52) U.S. Cl. 438/113

(57) ABSTRACT

A packing material for wafer packed up by stacking up a plurality of wafers, includes: a protective sheet protecting an optical surface being glued to an entire upper surface of the wafer; a dicing tape being concurrently glued to an entire lower surface of the wafer; and a first buffer being inserted in between each of the plurality of wafers and stacked up, whereafter both ends being protected with a second buffer.

### BACKGROUND OF THE INVENTION

1. Technical Field

The invention relates to a packing material for wafer, particularly to a simple, highly reliable packing material for wafer which is required when shipping an optical part of a wafer, a semi-finished product, to other plants.

2. Related Art

While a digital camera, optical pickup apparatuss capable of conducting recording/reproducing of information properly for optical disk and the like come into general use, their prices continue to drop. Lower prices of optical parts used for these products are likewise called for, hence, optical parts manufacturers are making constant efforts to cut back costs of manufacturing the optical parts.

As is well known, in the same way as manufacturing semi-conductor parts, the optical part is subjected to coating of an optical thin film and the like in one lot while in a condition of a mother board (hereinafter referred to as a “wafer”). Thereafter, dicing is performed to divide the optical part into pieces.

Next, after a rinsing process, visual inspection is carried out, piece by piece, to select acceptable item and not acceptable items. Only the acceptable item is placed in a packing case and the like and delivered to the customer as the optical part.

On the other hand, as referenced above, cost of coating of the optical thin film which determines optical properties of the optical part can be held low by processing in one lot, while a single item of the optical part produced by dicing into pieces relies on manual work in rinsing, inspection, and packing. Particularly, in regard to visual inspection, the present situation is that there is no recourse but to rely on manual work. Cost reduction of the optical part has its limits.

Now optical parts manufacturers are engaged in cutting back overall costs by moving processes such as visual inspection, which require manpower, to overseas where labor is relatively cheap. As a result, in the latter phase of the manufacturing process of the optical part, there is a need to transport the wafer, which has been coated, to other plants. Holding down this transport cost is of critical importance in lowering the cost of the optical part.

As a currently available technique, there is a method of placing a mouth-like buffer in a framework between wafers, stacking up wafers in several layers and packing them up.

FIG. 3 is an example of the currently available method of packing up wafers. As shown in FIG. 3, a wafer 1 is inserted in between buffers 2, and this is stacked up in several layers with its periphery protected by a protection plate which is fixed by rubber, tape and the like.

Because this packing method has the buffer 2 in a shape of a frame, an effective portion of an optical surface of the wafer 1 is made open, thus preventing the effective portion of the wafer 1 from being contaminated and the like. And yet, there is a drawback in that shavings generated when the buffer 2 is stamped into the shape of a frame are caught between the wafer 1 and the buffer 2, causing damage to the effective portion of the wafer 1 due to rubbing through vibration during shipment.

Accordingly, as a way to prevent this drawback, a new packing method is disclosed in Japanese Unexamined Patent Publication JA-10-230975.

FIG. 4 is an external view of buffers used for the packing method disclosed according to Japanese Unexamined Patent Publication JA-10-230975. In the packing method disclosed according to Japanese Unexamined Patent Publication JA-10-230975, as shown in FIG. 4, a buffer 3 has a section shaped in a letter L with a plurality of wafer insertion grooves 4 set inside along the letter L, so that a plurality of four corners of the wafers are inserted into the wafer insertion grooves 4 of the four buffers 3 to form a cube. The cube is fixed by using rubber, tape and the like.

According to this packing method, by inserting the wafer's corner part into the wafer insertion groove 4 of the buffer 3, a gap between the wafers is secured to provide for protection of the effective portion of the wafer, thereby preventing damage to the effective portion of the wafer due to rubbing of dust and the like.

Japanese Unexamined Patent Publication JA-10-230975 is an example of related art.

Nevertheless, when corresponding to wafers of various shapes, the buffer in the currently used shape of the letter L needs to be made in various dimensions to fit wafer sizes. This means considerable cost burden in terms of outlay for dies for manufacturing the buffers. Consequently, shipping cost of wafers becomes substantial, hampering efforts to lower the cost of optical parts.

### SUMMARY

An advantage of some aspects of the invention is to provide a packing material of high reliability when transporting wafers and to reduce the shipping cost.

According to a first aspect of the invention, a packing material for wafer packed up by stacking up a plurality of wafers, the packing material including: a protective sheet protecting an optical surface being glued to an entire upper surface of the wafer; a dicing tape being concurrently glued to an entire lower surface of the wafer; and a first buffer being inserted in between each of the plurality of wafers and stacked up, whereafter both ends being protected with a second buffer.

According to a second aspect of the invention, the packing material for wafer packed up by stacking up a plurality of wafers, the packing material, including: the protective sheet protecting an optical surface being glued to the entire upper surface of the wafer; the dicing tape being concurrently glued to the entire lower surface of the wafer; the protective sheet then being glued to the wafer; and the plurality of wafers being stacked up with a first buffer inserted in between each wafer, whereafter both ends are protected with a second buffer.

According to a third aspect of the invention, the packing material for wafer is wherein the first buffer is constituted by a soft sheet form of polyethylene foam.

According to a fourth aspect of the invention, the packing material for wafer includes the second buffer which is constituted by a soft sheet form of polyethylene foam.

According to the first, third, and fourth aspects of the invention, the packing material includes a plurality of wafers stacked up with a first buffer inserted in between each wafer after the entire surfaces of the wafer are covered with the protective sheet and the dicing tape. Since the first buffer does not directly contact the wafer surface, there is no risk of generating damage or breakage due to vibration, shock and the like during shipment.

At the same time, the dicing tape is glued to a lower side of the wafer to enable dicing to be carried out in the latter phase of processing after transport of the wafer, thus simplifying the manufacturing process of the optical part.

Further, all that is needed is cutting the buffer sheet to a wafer size so that no die is necessary for making the buffers, thus bringing about large effect in reducing the wafer shipping cost.

According to the second aspect of the invention, in addition to the features of the invention described in the first aspect, a protective sheet is glued to the surface of the dicing tape. This prevents the surface of the dicing tape from being contaminated, making it possible to perform cutting stably when dicing and producing large effect in improving the reliability of dicing which is performed after the wafer is transported.

### BRIEF DESCRIPTION OF THE DRAWINGS

The invention will be described with reference to the accompanying drawings, wherein like numbers refer to like elements.

FIGS. 1A and 1B are structural diagrams showing an example of a first embodiment of a packing material for wafer according to the invention.

FIGS. 2A and 2B are structural diagrams showing an example of a second embodiment of a packing material for wafer according to the invention.

FIG. 3 is an example of a currently available method of packing method of wafers.

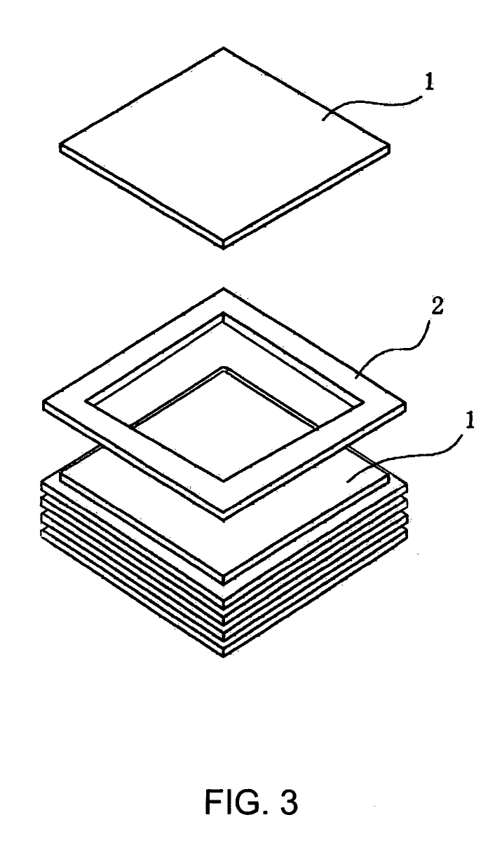

FIG. 4 is an external diagram of buffers used for a packing method disclosed in Japanese Published Patent JA-10-230975.

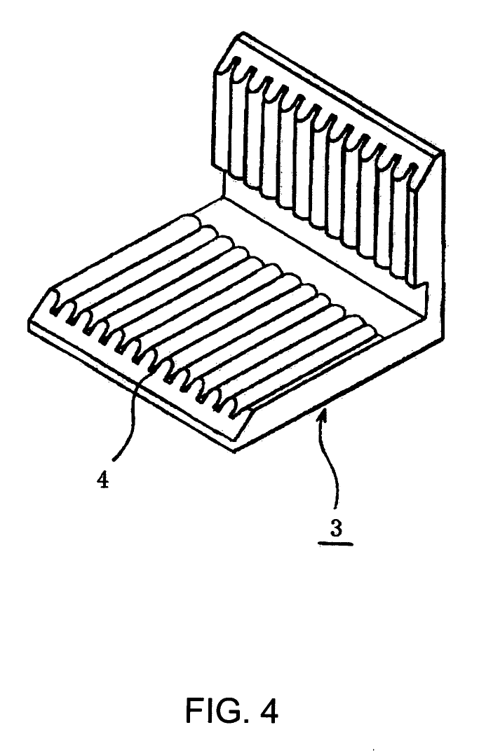

### DESCRIPTION OF THE EMBODIMENTS

The invention will be described below in detail with reference to illustrated examples of embodiments as follows.

In the invention, when transporting a wafer, packing is carried out as follows: a protective sheet protecting an optical surface is glued to an entire upper surface of the wafer, while a dicing tape is glued to an entire lower side of the wafer and a plurality of wafers are stacked up with a first buffer inserted in between each wafer.

A latter phase of the process after transporting the wafer consists of cutting it into pieces of an optical part through dicing, rinsing, external inspection, packing, and shipping. As a result, the dicing tape is glued to the lower surface of the wafer in advance to protect the lower surface thereof, which is then transported, while, after shipment, the wafer can be subjected to dicing as is. Consequently, because the wafer's surface is not directly in contact with the first buffer, it is possible for a simple packing material to prevent damage and breakage due to vibration, shock and the like during shipment.

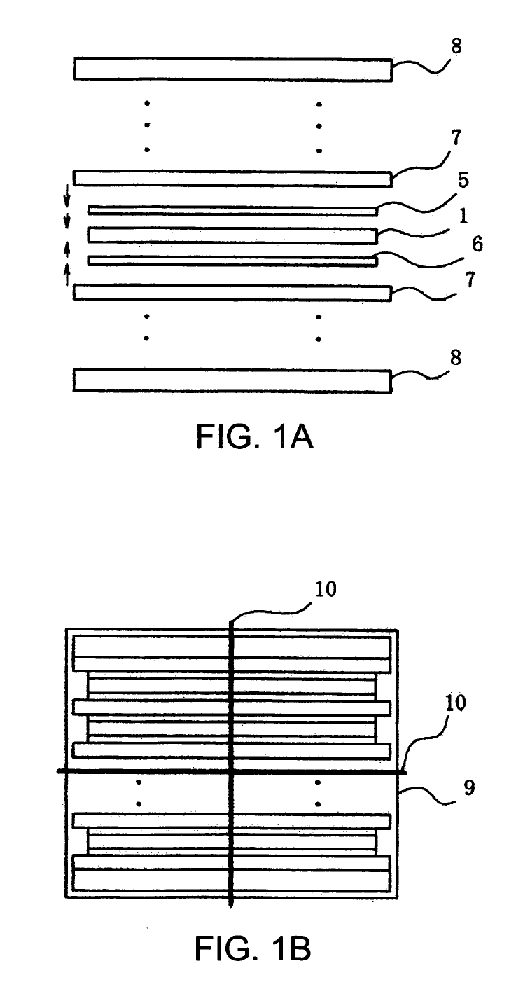

FIGS. 1A, 1B and 1C are structural diagrams showing an example of a first embodiment of a packing material for wafer according to the invention. FIG. 1A shows an exploded view of the packing material, while FIG. 1B shows the packing material in a state of being packed up in a vinyl plastic bag. As shown in FIGS. 1A and 1B, the invention is as follows: a protective sheet 5 is glued to an entire upper surface of a wafer 1, while a dicing tape 6 is glued to an entire lower surface of the wafer 1, whereafter a first buffer 7 of a size fit to a size of the wafer 1 is inserted between each of the plurality of wafers 1, wafers 1 being stacked up. A final step is placing a second buffer 8 on both ends with an entire lot wrapped up in a vinyl plastic bag 9 and fixed by rubber or a tape 10.

According to the invention, since both surfaces of the wafer 1 are glued with the protective sheet 5 and the dicing tape 6 which cover the entire surfaces, it is not necessary to process the first buffer 7 inserted between the wafers 1 into the shape of a frame, thereby reducing processing cost of the first buffer 7 by a big margin. At the same time, the wafer 1 is fully covered over the entire surfaces with the protective sheet 5, the dicing tape 6, and the first buffer 7, hence, movement of the wafer 1 relating to vibration during shipment is suppressed, creating no problem of dust generating due to rubbing between the wafer 1 and the first buffer 7. There is also no risk of damage and breakage.

Further, for example, when opening a vinyl plastic bag and taking out the wafer 1 at an overseas destination, the entire surfaces of the wafer 1 are covered with the protective sheet and the dicing tape 6, so that it is possible to prevent dirt from hands and finger marks as well as dust from adhering to and contaminating the optical surface of the wafer 1. Still further, when dicing is performed at an overseas destination, by peeling off only the protective sheet on the upper surface of the wafer 1, the wafer 1 can be set on a dicing device, thereby saving efforts of rinsing the wafer 1 and gluing the dicing tape thereto and contributing to cost reduction of the optical part.

Furthermore, contrary to the currently available packing method of using buffers shaped in the L letter, it is not necessary to prepare dies to make buffers fitting wafer sizes for accommodating wafers of various shapes. Consequently, cost burden of dies is reduced and transport cost of wafers is cut back, so that it is possible to bring about lower cost of the optical parts.

As the protective sheet 5 used in the invention, it is preferable to use a material suited as a surface protective material of the optical part, having good initial adhesion and light peeling property. Further, it should have such property that makes it hard for dust and lint to be attached to it when gluing the sheet or peeling it.

Moreover, a level of contamination of the wafer 1 due to gluing the protective sheet must be such as not to affect the optical properties of the optical part in terms of micron. Specifically, for example, there are commercially available products such as an olefin film, about 45 μm thick, coated with an adhesive. Accordingly, a protective sheet satisfying such properties is fit to the wafer 1, cut and used.

On the other hand, the dicing tape 6 is what is used when dicing the wafer 1. It purports to facilitate adsorption when the wafer 1 is adsorbed to a processing table of the dicing device, together with a function of preventing chips of pieces produced by dicing from flying around.

Specifically, for example, products with polyvinyl chloride (PVC), about 70-150 μm, polyolefin (PO), polyethyleneterephthalate (PET) and the like which are coated with adhesives are used. A dicing tape using PVC is available at low cost, but its adhesion is weak such that when dicing, a blade may incur damage. However, a dicing tape using PO or PET has strong adhesion. When dicing, the blade will not suffer damage; and by irradiating ultraviolet rays, detaching the wafer 1 is made easy, thus enabling stable dicing to be made.

In the invention, in the latter phase of the process carried out at the destination, dicing is first conducted. Hence, prior to shipping, the dicing tape is glued to the lower surface of the wafer 1 in advance to provide a function as the protective sheet of the wafer 1. Thereupon, the dicing tape satisfying such property fit to the wafer 1 is cut to preset dimensions and used.

Next, as the first buffer 7 used for the invention, it is possible to use general-purpose buffers which are normally available commercially, such as cushioning material of a foaming sheet, an elastic member and an engineering plastic cardboard. For example, what is used consists of a soft sheet buffer of foam polyethylene which is fit to the size of the wafer 1, cut to preset dimensions, and used.

On the other hand, the second buffer 8 protects all that is constituted by stacking up a plurality of wafers 1. The second buffer 8 is a general-purpose buffer, such as cushioning material of a foaming sheet, an elastic member and an engineering plastic cardboard. For example, a polypropylene material, approx. 2.5 mm thick, in sheet form used as buffers, architectural care, and other general-purpose items can be used by fitting it to the wafer 1 size, cut to preset dimensions, and used.

Next, as for the packing material for wafer according to the invention, an example of a second embodiment will be described.

When cutting the wafer into pieces of the optical part, there may be a case where, depending on the dicing device, jigs and the like used thereby, a degree of contamination (adhered dust and the like) of the surface of the dicing tape glued to the lower surface of the wafer becomes a matter of concern. Even in such a case, after the dicing tape is glued to the lower surface of the wafer, a protective sheet like the protective sheet glued to the upper surface of the wafer may be further glued thereto so as to protect the surface of the dicing tape from contamination.

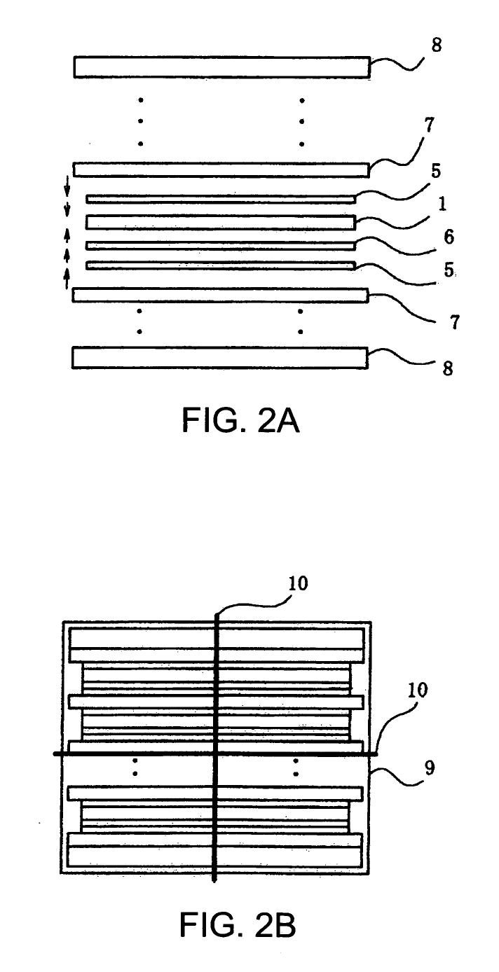

FIGS. 2A and 2B are structural diagram showing an example of a second embodiment of the packing material according to the invention. FIG. 2A shows an exploded view of the packing material, while FIG. 2B shows the packing material in a state of being packed up in a vinyl plastic bag. As shown in FIGS. 2A and 2B, the invention is as follows: a protective sheet 5 is glued to the entire upper surface of the wafer 1, while the dicing tape 6 is glued to the entire lower surface of the wafer 1, whereafter, the first buffer 7 of a size fit to the size of the wafer 1 is inserted between each of the plurality of wafers 1 and wafers 1 are stacked up. A final step is placing the dump plate 8 on both ends with an entire lot wrapped up in the vinyl plastic bag 9 and fixed with rubber or the tape 10.

According to the invention, by gluing the protective sheet 5 to both surfaces of the wafer 1, the entire surface of the wafer 1 is covered by the protective sheet 5. As a result, there is no need to process into the shape of frame the first buffer 7 to be inserted in between each wafer 1 like the first embodiment, so the processing cost of the first buffer 7 can be largely reduced. Further, since the wafer 1 is protected by the protective sheet 5 and the first buffer 7, the movement of the wafer 1 during shipment is suppressed, creating no problem of dust generating due to rubbing between the wafer 1 and the first buffer 7. There is also no risk of damage and breakage.

Furthermore, for example, when opening the vinyl plastic bag and taking out the wafer 1 at the overseas destination, the wafer 1 is fully covered by the protective sheet 5, so that dirt from hands as well as dust are prevented from adhering to and contaminating the optical surface of the wafer 1.

Moreover, when dicing at the overseas destination, by peeling off only the protective sheet 5 on the upper surface of the wafer 1 as well as the protective sheet 5 on the lower surface, the wafer 1 can be set on a dicing device, thereby saving efforts of rinsing the wafer 1 and gluing the dicing tape thereto and contributing to cost reduction of the optical part.

Furthermore, contrary to the currently available packing method of using buffers shaped in the L letter, it is not necessary to prepare metal molds to make buffers fitting wafer sizes for accommodating wafers of various shapes. Consequently, the cost burden of metal molds is reduced and transport cost of wafers is cut back, so that it is possible to bring about lower cost of the optical part.

1. A packing material for wafer packed up by stacking up a plurality of wafers, comprising:
a protective sheet protecting an optical surface being glued to an entire upper surface of the wafer;
a dicing tape being concurrently glued to an entire lower surface of the wafer; and
a first buffer being inserted in between each of the plurality of wafers and stacked up, whereafter both ends being protected with a second buffer.

2. The packing material for wafer packed up by stacking up a plurality of wafers, comprising:
the protective sheet protecting an optical surface being glued to the entire upper surface of the wafer;
the dicing tape being concurrently glued to the entire lower surface of the wafer;
the protective sheet then being glued to the wafer; and
the plurality of wafers being stacked up with a first buffer inserted in between, whereafter both ends are protected with a second buffer.

3. The packing material for wafer according to claim 1, wherein the first buffer is a soft sheet form of foam polyethylene.

4. The packing material for wafer according to claim 1, wherein the second buffer is a sheet form made of polypropylene with a preset thickness.

5. The packing material for wafer according to claim 1, wherein the second buffer is an engineering plastic cardboard.
